(19) United States
(12) Patent Application Publication
(10) Pub. No.: US 2006/0118952 A1
(43) Pub. Date: Jun. 8, 2006

(54) Micro-hole plating method, gold bump fabrication method and semiconductor device fabrication method using the micro-hole plating method, semiconductor device

(76) Inventors: Yoshihide Suzuki, Kurashiki-shi (JP); Keiichi Sawai, Fukuyama-shi (JP)

Correspondence Address: MORRISON & FOERSTER LLP, 755 PAGE MILL RD, PALO ALTO, CA, 94304-1018, US

(21) Appl. No.: 11/266,095

(22) Filed: Nov. 2, 2005

(30) Foreign Application Priority Data
Nov. 2, 2004 (JP) 2004-319902

(51) Int. Cl. H01L 23/48; H01L 21/44

(52) U.S. Cl. 257/737; 438/686; 438/674; 257/769

(57) ABSTRACT

The present invention provides a micro-hole plating method for depositing a gold layer within a micro opening of a photoresist. The method applies a plating current, which is either only a positive pulse current or a positive/negative pulse current having an appropriate waveform, and also uses a gold plating solution containing gold iodide complex ions and a non-aqueous solvent. This plating solution is less toxic, not easily oxidized, and has a long life, thus offering great performance comparable with the cyanide-type gold plating solution. According to this method, unevenness of bump surface, bump height variation in the wafer, and the bump surface roughness are reduced, and the resulting gold bumps have highly reliable conduction. In addition to this, the method is immune to a short circuit among electrodes, which is caused by a crack in the resist.

This Nonprovisional application claims priority under 35 U.S.C. § 119(a) on Patent Application No. 319902/2004 filed in Japan on Nov. 2, 2004, the entire contents of which are hereby incorporated by reference.

### FIELD OF THE INVENTION

The present invention relates to a method for carrying out gold plating within a micro hole. Based on this method, the present invention provides fabrication methods for gold bumps and a semiconductor device, and also provides a semiconductor device. In particular, the present invention provides a plating method applicable for formation of projection-type electrodes (bumps), which are formed by depositing a gold layer within a micro hole using a gold plating solution containing gold iodide complex ions and a non-aqueous solvent. The solution is less toxic, not easily oxidized, and has a long life, thus offering great performance comparable with the cyanide-type gold plating solution.

### BACKGROUND OF THE INVENTION

TCP (Tape Carrier Package), COF (Chip On Film), COG (Chip On Glass) are typical conventional methods for high-density packaging of a semiconductor chip (semiconductor device). In these methods, a convex electrode called a bump is formed on an electrode pad of a semiconductor chip, and the semiconductor chip is mounted to a film substrate, a glass substrate etc. via the bump, using thermal compression, ACF (Anisotropy Conductive Film) or the like.

The bump formed on the semiconductor chip is often made of gold, and the gold bump is generally formed by electrolytic plating. A method for forming a gold bump by electrolytic plating is briefly described below with reference to FIG. 6.

First, on a semiconductor wafer 30 containing a semiconductor chip, a barrier metal 32 and a current film 33 are sequentially formed on a surface on which an electrode pad 31 is formed. Next, a photoresist (resist layer) 34 is formed over the barrier metal 32 and the current film 33, and an opening 34a is created by carrying out exposure on the target area on which the bump is to be formed. Next, the semiconductor wafer 30 having the opening 34a is set in a plating device containing gold plating solution so as to be subjected to electrolytic plating. As a result, a gold bump 35 grows on the opening 34a. Then, the photoresist film 34 is removed from the semiconductor wafer 30, and the current film 33 and the barrier metal 32 are etched, thereby completing the gold bump 35.

One of the traditional gold plating solutions is the one containing gold complex cyanide (hereinafter referred to as a cyanide-type gold plating solution), with which the resulting gold layer becomes fine and smooth. The cyanide-type gold plating solution is also stable and allows easy control, and therefore has been used for many technologies. However, cyan is highly toxic, thus requiring extra caution in working environment, or in disposal.

Therefore, various noncyanide type low toxic gold plating solutions have been proposed. For example, a gold plating solution containing gold sulfite complex ions (hereinafter referred to as sulfite-type gold plating solution) has been widely used. However, with this gold plating solution which is less toxic, sulfite ions in the solution tend to be readily oxidized by dissolved oxygen or oxygen in the atmosphere, and the useful life as a gold plating solution tends to be short. Accordingly, it has been required to take a measure to prevent oxidation, e.g. by nitrogen sealing (supply nitrogen to the plating device so that the operation area and the tube are filled with nitrogen), during the storage or even during the plating operation, and thus, there has been a problem that its handling is cumbersome.

In view of this defect, Japanese Unexamined Patent Publication Tokukai 2004-43958 (published on Feb. 12, 2004) discloses gold plating solution containing iodine and iodide ions, gold iodide complex ions, and a non-aqueous solvent (hereinafter referred to as an iodine gold plating solution). This plating solution is less toxic, not easily oxidized, and has a long life, thus offering great performance comparable with the cyanide-type gold plating solution. Further, by carrying out plating using gold as the anode material, the gold as the anode will be dissolved into the plating solution so that the gold plating solution is supplied with gold in an amount balanced to the gold in the gold plating solution decreased by plating, thereby carrying out stabilized plating for a long period of time. This also allows easy plating with a gold alloy, which is not easy with the sulfite-type gold plating solution.

In a general semiconductor chip, more than 500 electrode pads are formed when the semiconductor chip serves as a component of a liquid crystal driver. To ensure connection strength and connection reliability for all of the large number of electrode pads, the heights of bumps must be even. If the bumps in the chip are made with different heights, the bumps may not be entirely bonded with the terminals of the film substrate or the glass substrate when the bumps and the terminals are joined through thermal compression or ACF during COG, TCP, or COF, thus causing operational defect of the semiconductor chip. Further, in addition to the variation in bump height, such a decrease of connection reliability between the bumps of the semiconductor chip and the terminals of the film substrate or the glass substrate may also be caused by unevenness of surface of the gold bump 35, as shown in FIG. 6.

In view of the problems of variation in bump height and exfoliation of resist during the plating, Japanese Unexamined Patent Publication Tokukaihei 10-223689 (published on Aug. 21, 1998) discloses a method of gold plating with respect to a micro hole by using a pulse source of 100 Hz to 10 kHz, with a duty ratio of 1/39 to 1/1 (2.5 to 50%). The resist exfoliation during the plating is more specifically a phenomenon in which the plating solution interfuses with the lower portion of the resist during the plating, causing the resist to be peeled off from the surface. As a result, the gold plating is carried out on the exfoliated resist, thereby causing a short circuit among the electrodes.

In spite of its advantages, the iodine gold plating solution described in Tokukai 2004-43958 quite easily causes unevenness of bump surface and variation in bump height (in the wafer) when the gold bumps are formed through the general electrolytic plating using a DC power source, compared with the gold bumps formed with a cyanide-type gold plating solution or a sulfite-type gold plating solution. In addition to this, iodine-type gold plating solution was found to easily cause a crack in the photoresist during the plating.

As described above, when the heights of bumps vary, or when the bump surface is uneven, the device (e.g., semiconductor chip) containing the bumps will has poor connection reliability, thus causing some kind of problem in the operation. Further, when a crack is generated in the photoresist as in the case of resist exfoliation, the plating solution soaks into the crack between the gold bumps, and a gold layer grows in the crack, thereby causing a short circuit among the electrodes. Besides, it is empirically proved that such a crack of photoresist often interferes complete removal of photoresist in the photoresist removal process.

Furthermore, it has been proved that the use of the iodine gold plating solution more easily results in generation of bump surface roughness, which is irregularity of bump surface, even when the foregoing technique disclosed in Japanese Unexamined Patent Publication Tokukaihei 10-223689 for preventing variation in bump height or resist exfoliation is employed. The bump surface roughness is illustrated in FIG. 6.

If such a bump surface roughness becomes excessively large, the bumps may not be entirely bonded with the terminals of the film substrate or the glass substrate in the step of joining the bumps and the terminals through thermal compression or ACF during COG, TCP, or COF, thereby reducing the bonding area. This defect occurs with or without variation of heights of bumps or the unevenness of bump surface, and results in operational defect of the semiconductor chip. Moreover, since the conductive particles for ACF are becoming smaller these days so as to be consistent with the narrow bump pitch in the recent devices, the reduction of bump surface roughness is urgently demanded.

### SUMMARY OF THE INVENTION

An object of the present invention is to provide a micro-hole plating method using a gold plating solution containing gold iodide complex ions and a non-aqueous solvent, the method offering the effect that the plating surface in a micro hole is even and smooth, and the heights of plating surfaces of all micro holes are equalized. Based on this method, the present invention provides fabrication methods for gold bumps and a semiconductor device, and also provides a semiconductor device.

In order to achieve the foregoing object, the micro-hole plating method for carrying out plating within a micro hole with gold according to the present invention comprises the step of: depositing a micro hole by applying a plating current, which is a positive current pulse wave, using a gold plating solution containing gold iodide complex ions and a non-aqueous solvent.

According to this method, gold plating is carried out within a micro hole by applying a plating current, which is a positive current pulse wave, from a pulse source. Therefore, by using an appropriate pulse current waveform; that is, by making the current density, the pulse-ON time, and the pulse-OFF time to appropriate values, the evenness and smoothness of plating surface in each micro hole are ensured, also making all the surfaces of micro holes to have the same heights. Further, when the micro holes are made on a resist layer, the resist will not be peeled off.

In order to achieve the foregoing object, the micro-hole plating method for carrying out plating within a micro hole with gold according to the present invention comprises the step of: depositing a gold layer within a micro hole by applying a plating current, which is a positive/negative current pulse wave, using a gold plating solution containing gold iodide complex ions and a non-aqueous solvent.

According to this method, plating is carried out within a micro hole by applying a plating current, which is a positive/negative current pulse wave, from a pulse source. Therefore, by using an appropriate pulse current waveform; that is, by making the positive current density, the negative current density, the positive pulse time, and the negative pulse time to appropriate values, the evenness and smoothness of plating surface in each micro hole are ensured, also making all the surfaces of micro holes to have the same heights. The effect is more significant in this case than the case above using a positive-only current pulse wave. Further, this case also prevents exfoliation of the resist even when the plating is carried out within the micro holes formed on a resist layer.

Owning to this fact, this plating method is applicable for forming gold bumps in fabrication of a semiconductor device, offering the effect of reducing unevenness of bump surface, bump height variation in the wafer, and the bump surface roughness. In the resulting semiconductor device, the reliability of conduction between the gold bumps are ensured, avoiding a decrease in yield due to a short circuit among electrodes caused by a crack in the resist. On this account, it is possible to manufacture a semiconductor device with a high yield.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a waveform diagram showing a waveform of positive plating pulse current used in the gold plating process for forming bumps, according to one embodiment of the present invention.

FIG. 2 is a is a waveform diagram showing a waveform of positive/negative plating pulse current used in the gold plating process for forming bumps, according to another embodiment of the present invention.

FIGS. 3(a) through 3(e) are cross-sectional views illustrating a major part of a semiconductor chip in a step for forming gold bumps by carrying out gold plating on electrode pads of the semiconductor chip.

FIG. 4 is a drawing according to an example of the present invention, showing respective dependencies of (i) current density CD (mA/cm²), (ii) pulse-ON time Ton (msec), and (iii) pulse-OFF time Toff (msec), with respect to unevenness of bump surface, bump height variation in the wafer, bump surface roughness, and a crack on photoresist.

FIG. 5 is a drawing according to an example of the present invention, showing respective dependencies of (i) negative current density CDr (mA/cm²), and (ii) negative pulse time Tr (msec), with respect to unevenness of bump surface, bump height variation in the wafer, bump surface roughness, and a crack on photoresist.

FIG. 6 is a cross sectional view illustrating a major part of a semiconductor chip in a step for forming gold bumps using a conventional gold plating.

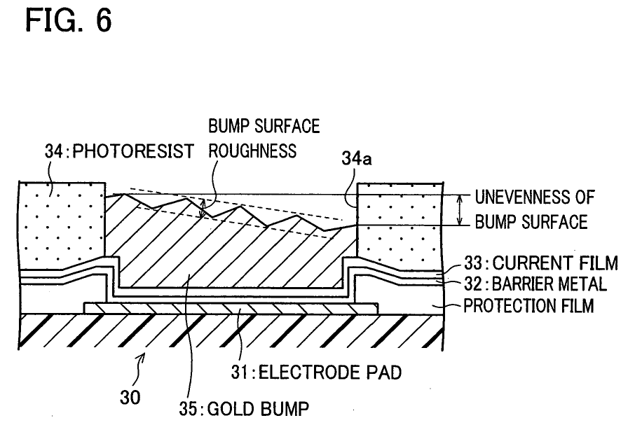

### DESCRIPTION OF THE EMBODIMENTS

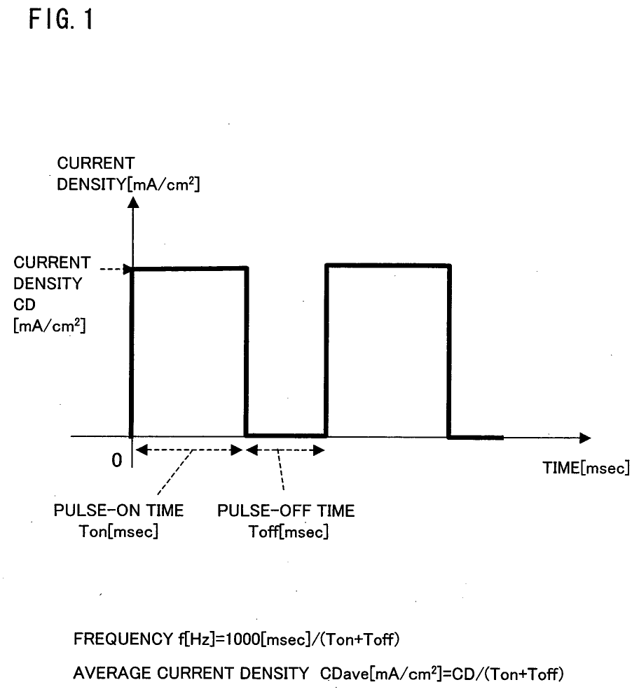

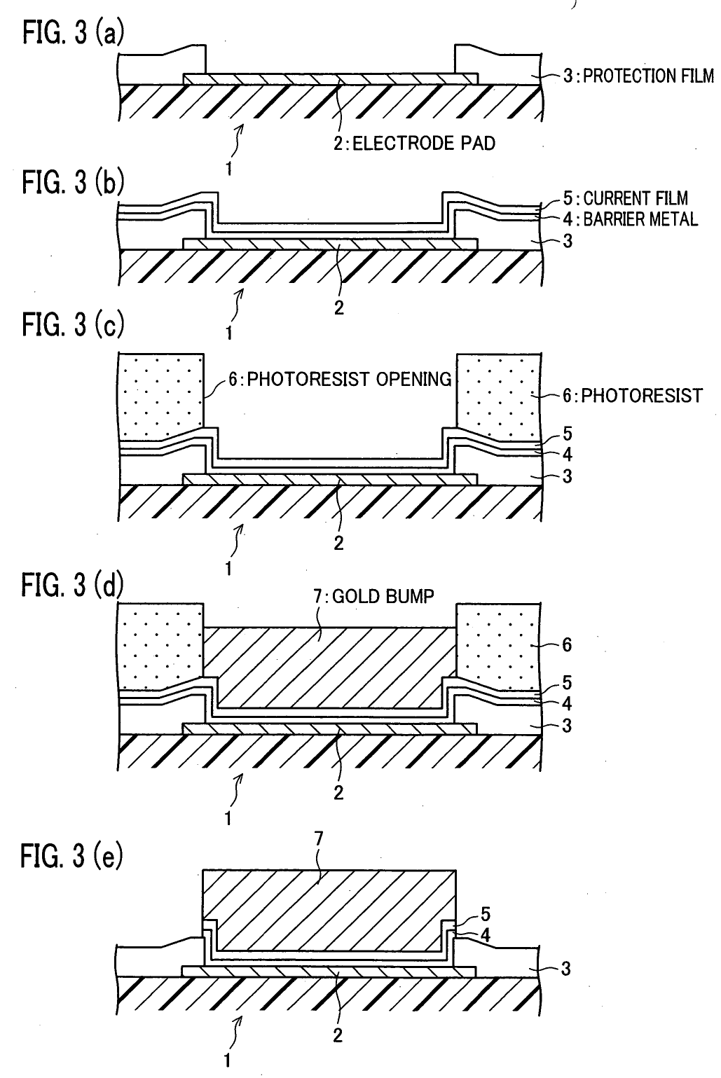

The following explains the present invention in detail by describing one embodiment of the present invention with reference to FIGS. 1 and 3. The present invention is applicable for fabrication of micro metal umbonal objects, such as bumps on an electrode pad of a semiconductor device.

First of all, the present invention carries out plating within micro holes by using a conventional gold plating solution, which is described in Japanese Unexamined Patent Publication Tokukai 2004-43958, or other documents. The gold plating solution contains gold iodide complex ions, and a non-aqueous solvent, more specifically, iodide ion (iodine and iodide ions), gold iodide complex ions, and a non-aqueous solvent.

The aqueous solution containing iodine (I₂) and iodide ions (I) is known as a solution for dissolving gold, in the form of gold iodide complex ion. Therefore, the gold aqueous solution obtained by dissolving gold in the aqueous solution is applicable for gold plating (electrolytic gold plating). Further, the non-aqueous solvent contained in the solution serves to suppress electrolysis of water, thereby forming a high quality gold film.

The iodide ions in the gold plating solution of the present invention are preferably prepared by using an iodide and the like. The cation of the iodide to be used is not particularly limited so long as it permits gold to be dissolved stably and it presents no adverse effect to the gold plating. Specifically, such a cation may, for example, be an alkali metal ion, an ammonium ion, a primary, secondary, tertiary or quaternary alkyl ammonium ion, a phosphonium ion or a sulfonium ion, preferably an alkali metal ion such as a sodium ion or a potassium ion, particularly preferably a potassium ion. These cations may be used alone or in combination of two or more cations.

The gold iodide complex ions in the gold plating solution of the present invention can be prepared in accordance with the following formula (1) or (2). Namely, there may, for example, be a method of preparing them by electrolytically dissolving gold in a solution containing iodide ions and a non-aqueous solvent or in such a solution having an oxidizing agent added, or a method of preparing them by dissolving gold in a solution comprising iodide ions, a non-aqueous solvent and an oxidizing agent.
Au+2I⁻→[AuI₂]⁻+e⁻ (1)
2Au+I₂+2I⁻→2[AuI₂]⁻ (2)

Here, as the oxidizing agent, iodine (I₂) may directly be used, or an oxidizing agent to oxidize iodide ions (I⁻) in the plating solution to I₂, may be used. As such an oxidizing agent, any optional one may be used so long as it is capable of oxidizing iodide ions (I⁻) in the gold plating solution to I₂. For example, iodine (I₂), iodic acid (HIO₃), periodic acid (HIO₄) or a salt thereof, may be mentioned. Among them, it is preferred to use iodine (I₂) as the oxidizing agent when the gold plating solution of the present invention is to be prepared, taking into consideration the solubility in the solution and the stability in the solution.

The content of iodine element in the gold plating solution of the present invention may suitably be selected depending on the amount of gold iodide complex ions to be contained in the gold plating solution. That is, at the time of preparing the gold plating solution of the present invention, the amount of the oxidizing agent such as I₂ to be required for the desired dissolution amount of gold, may be selected as the case requires.

The content of iodine element in the gold solution designates a value obtained by measuring, on an iodine element basis, the gross amount of iodide ions, gold iodide complex ions, and residue of I² if it is used to dissolve gold. The value may be found by measurement or by calculation according to the amount of material used for adjustment of plating solution. Accordingly, the content of iodine element in the gold plating solution of the present invention is not particularly limited, but it is usually at least 0.1 wt %, preferably at least 0.5 wt %, more preferably at least 1 wt %, particularly preferably at least 5 wt %. Further, the upper limit of this content is usually at most 75 wt %, preferably at most 50 wt %, more preferably at most 30 wt %, particularly preferably at most 20 wt %.

Further, in a case where the gold plating solution of the present invention contains both iodine (I₂) and iodide ions, the weight ratio of iodine (I₂) to iodide ions (iodine (I₂): iodide ions) is not particularly limited so long as gold can be stably dissolved, and unless the desired effects of the present invention will not be impaired.

However, if the iodine (I₂) content in the gold plating solution of the present invention is excessively high, there may be a case where, when a laminate of gold (or gold alloy) films is used as a cathode at the time of gold plating, dissolution of the electrode by iodine (I₂) in the gold plating solution is so much that the desired plating cannot be carried out. Accordingly, the iodine (I₂) content in the gold plating solution of the present invention is preferably as low as possible so long as the performance as the gold plating solution will not be impaired, and in a case where gold is used as the gold source, and iodine and iodide ions are used as the iodine source, the weight ratio of iodine (I₂): iodide ions at the time of filling, is usually from 1:2 to 1:1,000, preferably from 1:3 to 1:100, more preferably from 1:5 to 1:30.

The gold plating solution of the present invention further contains a non-aqueous solvent. The gold plating solution of the present invention may contain the non-aqueous solvent and water. The type of the non-aqueous solvent is not particularly limited so long as plating can be carried out satisfactorily, and it provides a sufficient solubility for the solute. However, a compound having an alcoholic hydroxyl group and/or a phenolic hydroxyl group, or an aprotic organic solvent, is preferred.

As the compound having an alcoholic hydroxyl group, a monohydric alcohol such as methanol, ethanol, propanol or isopropanol; a dihydric alcohol such as ethylene glycol or propylene glycol; or a tri or higher polyhydric alcohol may be employed.

Among them, one having two or more alcoholic hydroxyl groups, such as a dihydric alcohol or trihydric alcohol, is preferred. Specifically, ethylene glycol, propylene glycol is preferred, and ethylene glycol is particularly preferred.

As the compound having a phenolic hydroxyl group, one having a single hydroxyl group such as unsubstituted phenol, or an alkyl phenol such as o-, m- or p-cresol or xylenol, or one having two hydroxyl groups, such as a resorcinol, or one having three hydroxyl groups, such as a pyrogallol, may, for example, be used.

As the non-aqueous solvent, a compound having a functional group other than an alcoholic hydroxyl group or a phenolic hydroxyl group in its molecule, may also be used so long as it does not hinder the desired effects of the present invention. For example, a compound having an alkoxy group together with an alcoholic hydroxyl group, such as methylcellosolve or cellosolve, may also be used.

The aprotic organic solvent may be a polar solvent or a non-polar solvent.

The polar solvent may, for example, be a lactone solvent such as y-butyrolactone, y-valerolactone or δ-valerolactone; a carbonate solvent such as ethylene carbonate, propylene carbonate or butylene carbonate; an amide solvent such as N-methylformamide, N-ethylformamide, N,N-dimethylformamide, N,N-diethylformamide, N-methylacetamide, N,N-dimethylacetamide or N-methylpyrrolidinone; a nitrile solvent such as 3-methoxy propylonitrile or glutalonitrile; or a phosphate solvent such as trimethyl phosphate or triethyl phosphate.

The non-polar solvent may, for example, be hexane, toluene or silicone oil. These non-aqueous solvents may be used alone or in combination of two or more of them. In the gold plating solution of the present invention, a particularly preferred non-aqueous solvent is ethylene glycol or y-butyrolactone alone or its mixture with any one of the above-mentioned non-aqueous solvents.

The content of the non-aqueous solvent in the gold plating solution of the present invention is usually at least 10 wt %, preferably at least 30 wt %, more preferably at least 50 wt %, particularly preferably at least 55 wt % and usually at most 95 wt %, preferably at most 90 wt %, more preferably at most 85 wt %, particularly preferably at most 80 wt %, based on the entire gold plating solution.

In a case where the gold plating solution contains water, the content is usually at least 1 wt %, preferably at least 5 wt %, further preferably at least 7 wt %, particularly preferably at least 10 wt %, and usually at most 85 wt %, preferably at most 50 wt %, more preferably at most 40 wt %, particularly preferably at most 30 wt %, based on the entire gold plating solution.

The proportion of water to the non-aqueous solvent is usually at least 1 wt %, preferably at least 5 wt %, more preferably at least 7 wt %, particularly preferably at least 10 wt %, and usually at most 90 wt %, preferably at most 60 wt %, more preferably at most 50 wt %, particularly preferably at most 40 wt %.

The gold plating solution of the present invention is an excellent gold plating solution which contains substantially no cyanide, whereby it is excellent in safety, the waste liquid treatment will be easy, and the load to the environment will be low. Here, “contains substantially no cyanide.” means not to positively incorporate cyanide for the purpose of gold plating, and it is preferred that the solution is completely cyanide-free. For example, in a case where cyanide will be included as an impurity during the preparation of the gold plating solution of the present invention, the content of cyanide is, of course, preferably as small as possible, and specifically, it is preferably at most 1 wt %, more preferably at most 0.1 wt %, particularly preferably at most 0.01 wt %.

The reason as to why it has been made possible to carry out gold plating effectively by incorporating the non-aqueous solvent to the gold plating solution, is not clearly understood. However, it is conceivable that by the presence of the non-aqueous solvent, generation of gas due to hydrolysis of water at the cathode is suppressed, whereby the efficiency in reduction and deposition of gold is improved.

The gold plating solution of the present invention may further contain an additive capable of improving the characteristics of the plated film. Such an additive may be at least one substance selected from additives and other substances which have been commonly used in known cyanide-type or sulfite-type plating solutions, unless it hinders the desired effects of the present invention. The amount of such an additive is not particularly limited, and a proper amount may be determined taking into the effects and costs into consideration.

Further, in the present invention, alloy plating may be carried out by dissolving at least one metal other than gold in the gold plating solution of the present invention. The metal other than gold may, for example, be copper, silver or tin, which is well known for a gold alloy (Kotoda, Hyomen Gijutsu, 47(2), 142(1996)). However, other metals may be employed so long as they can be dissolved in the gold plating solution of the present invention. At that time, in order to dissolve the metal other than gold, an anion other than an iodide ion may be added unless it hinders the desired effects of the present invention.

The method for producing the gold plating solution of the present invention is not particularly limited. It can be obtained by mixing the gold source, the iodine source, the non-aqueous solvent, the and other optional additives.

Preferably, a method is employed wherein gold or a gold alloy is dissolved at room temperature, or by appropriate supplement of a solvent, in a solution containing iodine, iodide ions, the non-aqueous solvent.

The gold plating solution of the present invention is very stable as is evident from the fact that gold will be readily dissolved at room temperature in a solution containing iodine and iodide ions in accordance with the following formula (2). Accordingly, even when contacted with dissolved oxygen or oxygen in the atmosphere, gold iodide complex ions in the gold plating solution can be present stably.

Further, the gold iodide complex ions in the gold plating solution of the present invention are in an equilibrium represented by the following formula (3), whereby deposition of gold due to e.g. the above-mentioned disproportionation reaction scarcely takes place. Also, compared with the formula (3), the content of iodine and the content of iodide ions in the gold plating solution of the present invention is greatly biased to the left, that is the gold ion in the gold plating solution exists mostly as an iodine (I) gold complex ion. On this account, the present invention more efficiently carries out electrolytic plating with less amount of electricity.
[AuI₂]⁻+I₂+I⁻ [symbol] [AuI₄]⁻+I⁻ (3)

The gold source for the gold plating solution of the present invention may, for example, be a gold alloy or gold as a simple substance. However, with a view to preventing inclusion of impurities in the plating solution, simple substance gold or gold iodide is preferred. Among them, simple substance gold is particularly preferred from the viewpoint of availability. The simple substance gold may be in any form of block, foil, plate, particles or powder, depending on the process for producing the gold plating solution. Similarly, when an alloy is used, simple substance metal having the same composition as the alloy is preferred in consideration of composition of plating solution. In such a case, taking into the dissolution rate into consideration, there may be a case where as the alloy composition, a composition slightly departed from the composition of the plated film is employed.

The foregoing gold plating solution contains both iodine and iodide ions, and therefore shows great dissolving performance for gold. In the electrolytic plating method employing the gold plating solution of the present invention, if plating is carried out by using gold or a gold alloy to the material for an electrode (anode) opposite to an electrode (cathode) on the side where gold is deposited, it is possible to supply the gold or gold alloy component from the anode while carrying out plating at the cathode, whereby a stabilized operation will be possible wherein the gold concentration or the alloy component concentration in the gold plating solution is maintained to be always constant. By using gold or a gold alloy as the anode in this manner, plating can be carried out for a long time, and it is possible to prolong the useful life of the plating solution. When gold or a gold alloy is used as the anode, the composition and the shape are preferably suitably adjusted taking into consideration the decomposition of the gold plating solution, etc.

In the micro-hole plating method according to the present invention, the plating is carried out with respect to a substrate or the like having micro holes. That is, in the case of forming gold bumps on the electrode pads of a semiconductor chip through gold plating, the object of plating is a semiconductor wafer (the semiconductor product before divided into semiconductor chips), which is a substrate on which the semiconductor chip is formed with electrode pads. The diameter of the semiconductor wafer is generally 3, 4, 5, 6, 8 or 12 inches. Further, the substrate is generally made of aramid, alumina, glass, silicon, or gallium arsenide. On the electrode pads on the substrate, a barrier metal layer and a current film are laminated. The barrier metal layer is a thin film of a high-melting-point metal, such as Ti, Ti—W, Ti—N, Ni, W, Cr, Ta, Ta—N, or a compound thereof. The current film is a thin film of gold, silver, copper, an alloy of gold-silver, or an alloy of gold-copper. The thickness of substrate is not limited, but preferably in a range of 0.2 to 1.0 mm. The thickness of barrier metal layer is set in a range of about 0.05 to 0.5 μm, preferably about 0.1 to 0.3 μm. The thickness of current film is set in a range of about 0.05 to 0.7 μm, more preferably about 0.1 to 0.4 μm.

Then, a resist layer is formed on the current film, and micro holes are formed on the resist layer by opening portions corresponding to the electrode pads. The size of the micro hole is, for example, in a range of 100 to 40000 μm², more preferably 100 to 10000 μm²; The resist layer is formed on the substrate by a general method, such as spin-coating. The thickness of resist layer is, for example, in a range of 10 to 40 μm, more preferably 15 to 30 μm. The micro holes in the resist layer must be completely through to the current film. The number of electrode pads is about 1000 to 2250000. The gross area of bumps is about 0.001 to 225 cm².

The micro-hole plating method according to the present invention uses the foregoing gold plating solution, and carries out gold plating by applying a positive plating pulse current, or positive/negative plating pulse current to the micro holes using a pulse source.

More specifically, the plating is carried out by applying a positive plating pulse current, or positive/negative plating pulse current under the following condition. As shown in FIG. 1, a waveform of positive plating pulse current is expressed by (i) current density CD (mA/cm²), (ii) pulse-ON time Ton (msec), and (iii) pulse-OFF time Toff (msec). Here, the frequency f and the average current density CDave are expressed as follows.
f[Hz]=1000 [msec]/(Ton+Toff)
CDave[mA/cm²]=CD/(Ton+Toff)

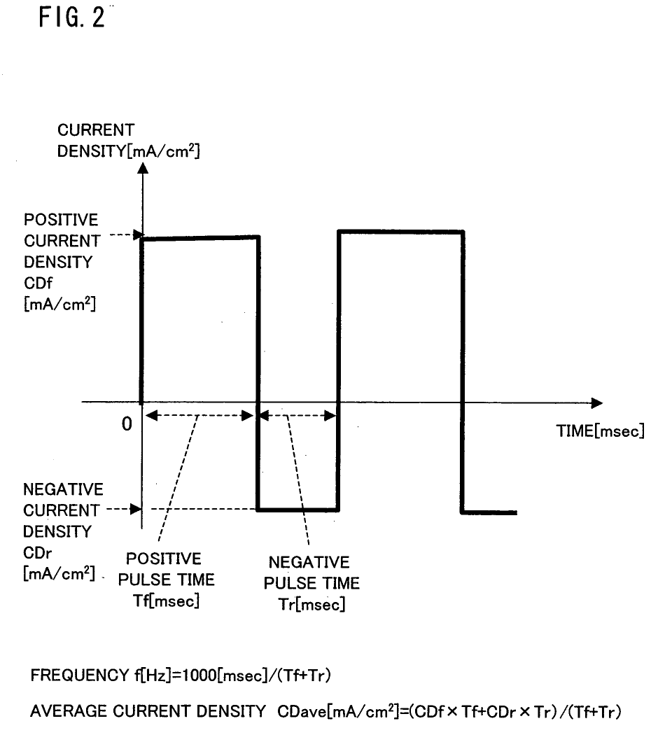

Further, as shown in FIG. 2, a waveform of positive/negative plating pulse current is expressed by (i) positive current density CDf (mA/cm²), and (ii) negative current density CDr (mA/cm²) and (iii) positive pulse time Tf (msec), and (iv) negative pulse time Tr (msec). Here, the frequency f and the average current density CDave are expressed as follows.
f[Hz]=1000 [msec]j/(Tf+Tr)
CDave[mA/cm²]=(CDf×Tf+CDr×Tr)/(Tf+Tr)

The following shows a preferable current pulse waveform for the plating current. In the positive current pulse wave, the current density CD (mA/cm²) is set in a range of 0<CD<20, more preferably 0.5≦CD≦15, further preferably 2≦CD≦6. The pulse-ON time Ton (msec) is set in a range of 0<Ton<10000, more preferably 1≦Ton≦5000, further preferably 1≦Ton≦1000. The pulse-OFF time Toff (msec) is set in a range of Toff>0.5, more preferably Toff≧1.

Note that, the current density, the pulse-ON time, and the pulse-OFF time may be determined with an arbitrary combination of the respective allowable ranges, preferable ranges and further preferable ranges.

With this condition, the evenness and smoothness of plating surface in each micro hole are ensured, also making all the surfaces of micro holes to have the same heights. Further, when the micro holes are made on a resist layer, the resist will not be peeled off.

In the positive/negative current pulse wave, the positive current density CDf (mA/cm²) is set in a range of 0<CDf<20, more preferably 0.5≦CDf≦15, further preferably 2≦CDf≦6. The negative current density CDr (mA/cm²) is set in a range of −20<CDr<0, more preferably −15≦CDr<0, further preferably −5≦CDr<0. The positive pulse time Tf (msec) is set in a range of 0<Tf<10000, more preferably 1≦Tf≦5000, further preferably 10≦Tf≦1000. The negative pulse time Tr (msec) is set in a range of Tr>0.5, more preferably Tr≧1. Note that, the positive and negative current densities, the positive pulse time, and the negative pulse time may be determined with an arbitrary combination of the respective allowable ranges, preferable ranges and further preferable ranges.

With this condition, the evenness and smoothness of plating surface in each micro hole are ensured, also making all the surfaces of micro holes to have the same heights. Further, when the micro holes are made on a resist layer, the resist will not be peeled off.

With this condition, the optimum current density and the optimum pulse time are used in the method for carrying out plating a micro hole by using a gold plating solution containing gold iodide complex ions and non-aqueous solvent. Consequently, the evenness and smoothness of plating surface in each micro hole are ensured, also making all the surfaces of micro holes to have the same heights. Particularly, application of positive/negative current offers better effect for the evenness and smoothness of plating surface in each micro hole are ensured, and for making all the surfaces of micro holes to have the same heights, than application of only positive current.

Therefore, by forming the gold bumps under this condition, it is possible to reduce unevenness of bump surface, bump height variation in the wafer, and bump surface roughness, thereby improving connection reliability. As well as this, a crack on photoresist will not occur whereby the short circuit among the electrodes is prevented. Consequently, the yield increases.

The following further specifically explains the present invention with concrete examples.

### EXAMPLE 1

As shown in FIG. 3(a), with a conventional technique, a semiconductor wafer 1 which is 8 inches in diameter was manufactured. This semiconductor wafer 1 includes (i) a semiconductor chip having an electrode pad 2 and (ii) a protection film 3. Then, as shown in FIG. 3(b), a barrier metal 4 and a current film 5 were formed in this order, by means of sputtering. The barrier metal 4 may be high-melting-point metal such as Ti, Ti—W, and Ti—N, or a compound thereof. In the present example, Ti—W 0.25 μm thick is adopted as the barrier metal 4. The current film 5 in the example is gold which is 0.3 μm thick.

Subsequently, as shown in FIG. 3(c), on the semiconductor wafer 1 on which the current film 5 was formed, a film of positive photoresist 6 which is 20 μm thick was formed by spin-coating, a bump forming portion on the electrode pad 2 was subjected to exposure, and an opening 6a was made through the photoresist film 6, by developing. In the present example, the semiconductor wafer 1 has 710,000 electrode pads and the area of the opening 6a of the photoresist 6 was 2.1E⁻⁵cm². The gross area of the bumps was 15 cm².

Subsequently, as shown in FIG. 3(d), gold was precipitated on the opening 6a of the photoresist 6, by electrolytic plating, so that a gold bump 7 was developed. In this step, the gold plating solution disclosed by Japanese Laid-Open Patent Application No. 2004-43958 was used. The gold plating solution includes gold iodide complex ions and a non-aqueous solvent, more specifically, the gold solution includes an iodide ion (iodide and iodide ions), gold iodide complex ions, and a non-aqueous solvent. The iodide element content of the gold plating solution is 0.5 to 50 (weight %), and the non-aqueous solvent is either (i) a compound including an alcoholic hydroxyl group and/or a phenolic hydroxyl group, or (ii) an aprotic solvent.

The power source for applying a plating current was a pulse power source, and the opposing electrode was a platinated titan mesh. A pulse current waveform of the plating current was a pulse waveform of positive-only current, which is shown in FIG. 1.

Subsequently, as shown in FIG. 3(e), the photoresist 6 was removed, and the current film 5 and barrier metal 4 were etched away to complete the gold bump 7.

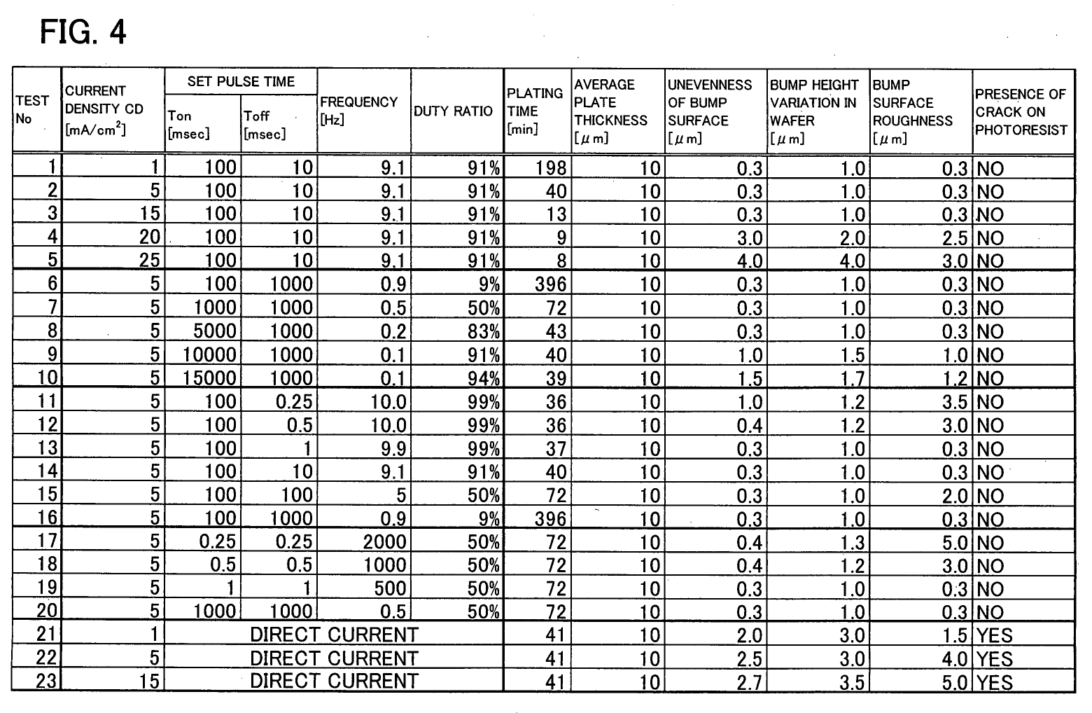

FIG. 4 is a drawing according to an example of the present invention, showing respective dependencies of (i) current density CD (mA/cm²), (ii) pulse-ON time Ton (msec), and (iii) pulse-OFF time Toff (msec), with respect to unevenness of bump surface, bump height variation in wafer, bump surface roughness, and a crack on photoresist.

Tests No. 1-5 are results of the measurement of the dependencies on current density CD, with the assumption that Ton is constant at 100 msec and Toff is constant at 10 msec. It was found that, when CD is 20 mA/cm² or more, the unevenness of bump surface, the bump height variation in wafer, and the bump surface roughness were all worse.

Tests No. 6-10 are results of the measurement of the dependencies on the pulse-ON time Ton, with the assumption that CD is constant at 5 mA/cm² and Toff is constant at 1000 msec. It was found that, when Ton is 10000 msec or more, the unevenness of bump surface, the bump height variation in wafer, and the bump surface roughness were all worse.

Tests 11-16 are results of the measurement of the dependencies on the pulse-OFF time Toff, with the assumption that CD is constant at 5 mA/cm² and Ton is constant at 100 msec. It was found that, when Toff is 0.5 msec or less, the unevenness of bump surface, the bump height variation in wafer, and the bump surface roughness were all worse.

Tests 17-20 are results of the measurement of the dependencies on the frequency [Hz], with the assumption that the duty ratio. Ton/(Ton+Toff) is constant at 50%. According to the result, the bump surface roughness was deteriorated when the frequency is not less than 1 kHz (Ton=Toff=0.5 msec or more). This indicates that the condition range (duty ratio=1/39 to 1/1 (2.5 to 50%), frequencies of 100 Hz to 10 kHz) disclosed in the aforesaid Japanese Laid-Open Patent Application No. 10-223689 is hardly applicable for a iodine-type plating solution.

According to this, the conditions of an optimum positive current pulse for performing the plating to form the gold bump by the iodine-type plating solution are set as follows: at least current density CD (mA/cm²) is 0<CD<20; the pulse-ON time Ton (msec) is 0<Ton<10000; the pulse-OFF time Toff (msec) is Toff>0.5, more preferably, 0.5≦CD≦15, 1≦Ton≦5000, and Toff≧1.

Taking into consideration of the productivity, the time required for 10 μm-thick plating is preferably not more than 60 min. Therefore, an average current density CDave (mA/cm²) is preferably not less than 3 mA/cm², more preferably not less than 4 mA/cm². Accordingly, a preferable upper limit of Toff is determined.

Tests No. 21-23 are results of the following experiment: with the semiconductor wafer, gold plating solution, and opposing electrode, which are identical with those in the Tests No. 1-20, the plating was carried out using a direct current with a current density CD=5 mA/cm². According to the results, the unevenness of bump surface, the bump height variation in wafer, and the bump surface roughness were significant, and a crack in the photoresist was observed. The results therefore proved the superiority of the pulse power source.

### EXAMPLE 2

As described above, since the conductive particles for ACF are becoming smaller these days so as to be consistent with the narrow bump pitch in the recent devices, the reduction of bump surface roughness is urgently demanded. To restrain the bump roughness, a pulse signal of opposite direction was applied.

Being similar to Example 1, as FIG. 3(a), a semiconductor wafer 1 that is 8 inches in diameter and has (i) a semiconductor chip with an electrode pad 2 and (ii) a protection film 3 was formed by a conventional technique. Then, as shown in FIG. 3(b), a barrier metal 4 and a current film 5 were formed in this order by sputtering. The barrier metal 4 may be high-melting-point metal such as Ti, Ti—W, and Ti—N, or a compound thereof. In the present example, Ti—W 0.25 μm thick is adopted as the barrier metal 4. The current film 5 in the example is gold which is 0.3 μm thick.

Subsequently, as shown in FIG. 3(c), on the semiconductor wafer 1 on which the current film 5 was formed, a film of positive photoresist 6 which is 20 μm thick was formed by spin-coating, a bump forming portion on the electrode pad 2 was subjected to exposure, and an opening 6a was made through the photoresist film 6, by developing. In the present example, the semiconductor wafer 1 has 710,000 electrode pads and the area of the opening 6a of the photoresist 6 was 2.1E⁻⁵cm². The gross area of the bumps was 15 cm².

Subsequently, as shown in FIG. 3(d), gold was precipitated on the opening 6a of the photoresist 6, by electrolytic plating, so that a gold bump 7 was developed. In this step, the gold plating solution disclosed by Japanese Laid-Open Patent Application No. 2004-43958 was used. The gold plating solution includes gold iodide complex ions and a non-aqueous solvent, more specifically, the gold solution includes an iodide ion (iodide and iodide ions), gold iodide complex ions, and a non-aqueous solvent. The iodide element content of the gold plating solution is 0.5 to 50 (weight %), and the non-aqueous solvent is either (i) a compound including an alcoholic hydroxyl group and/or a phenolic hydroxyl group, or (ii) an aprotic solvent.

The power source for applying a plating current was a pulse power source, and the opposing electrode was a platinated titan mesh. This pulse current waveform used as a plating current was a pulse waveform of positive/negative current, which is shown in FIG. 2.

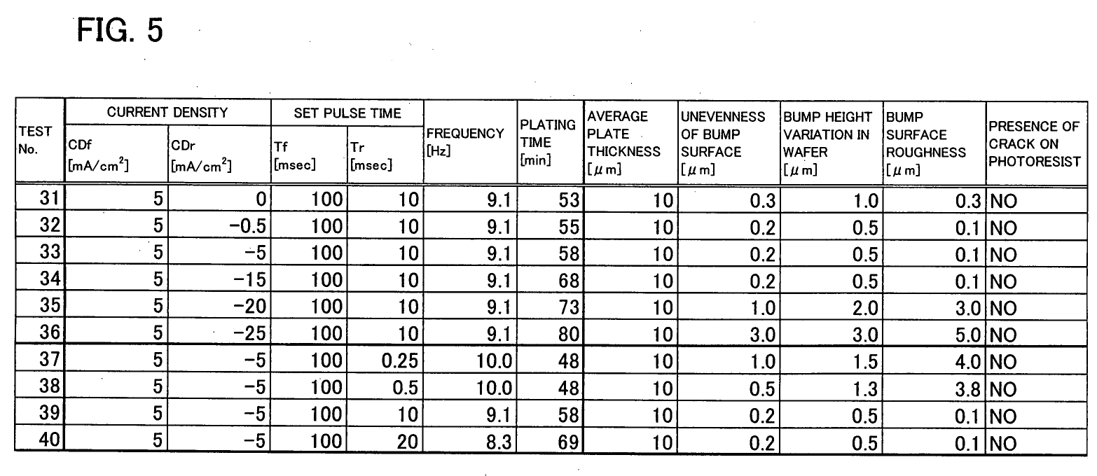

FIG. 5 is a drawing according to an example of the present invention, showing respective dependencies of (i) negative current density CDr (mA/cm²), and (ii) negative pulse time Tr (msec), with respect to unevenness of bump surface, bump height variation in wafer, and bump surface roughness, and a crack on photoresist. Also in this example, the plating time is adjusted so as to cause the plating thickness to be constant at 10 μm.

Tests 31-36 are results of the measurement of the dependencies on negative current density CDr, with the assumption that CDf is constant at 5 mA/cm², Tf is constant at 100 msec, and Tr is constant at 10 msec. As compared to the case of CDf=0 mA/cm² (corresponding to the case of the pulse wave of only a positive current), the unevenness of bump surface, the bump height variation in wafer, and the bump surface roughness were improved, in the range of CDr=−0.5 to −15 mA/cm². Also, no crack in the photoresist was observed. In a case where CDr is −20 mA/cm² or less, the unevenness of bump surface, the bump height variation in wafer, and the bump surface roughness were all worse.

Tests 37-40 are results of the measurement of the dependencies on the negative pulse time Tr (msec), with the assumption that CDf is constant at 5 mA/cm², CDr is −5 mA/cm², and Tf is constant at 100 msec.

It was found that, when Tr is 0.5 msec or less, the unevenness of bump surface, the bump height variation in wafer, and the bump surface roughness were all worse.

As a result of the above, in the positive/negative current pulse wave which is optimum at the time of carrying out plating for the formation of the gold bump by means of a iodine-type plating solution, the negative current density CDr (mA/cm²) is set in a range of −20<CDr<0, more preferably −15≦CDr<0, further preferably −15≦CDr≦−0.5. As in the case of Toff in Example 1, the negative pulse time Tr (msec) is preferably more than 0.5, more preferably not less than 1.

The current density CD and pulse-ON time in regard of the positive pulse Tf may be identical with those of Example 1. That is, the positive current density CDf (mA/cm²) is 0<CDf<20 and the pulse-ON time Tf (msec) is 0<Tf<10000, more preferably 0.5≦CDf≦15 and 1≦Tf≦5000.

Also taking into consideration of the productivity, the time required for 10 μm-thick plating is preferably not more than 60 min. Therefore, an average current density CDave (mA/cm²) is preferably not less than 3 mA/cm², more preferably not less than 4 mA/cm². According to this, a preferable upper limit of Toff is determined.

As described, a micro-hole plating method according to the present invention is a method for carrying out gold plating within a micro hole, comprising the step of: depositing a gold layer within a micro hole by applying a plating current, which is a positive current pulse wave, using a gold plating solution containing gold iodide complex ions and a non-aqueous solvent.

According to this method, gold plating is carried out within a micro hole applying a plating current, which is a positive current pulse wave, from a pulse source. Therefore, by using an appropriate pulse current waveform; that is, by making the current density, the pulse-ON time, and the pulse-OFF time to appropriate values, the evenness and smoothness of plating surface in each micro hole are ensured, also making all the surfaces of micro holes to have the same heights.

The positive current pulse wave is set such that a current density CD (mA/cm²) satisfies 0<CD<20, a pulse-ON time Ton [msec] satisfies 0<Ton<10000, and a pulse-OFF time Toff [msec] satisfies Toff>0.5. Therefore, by applying a plating current satisfying the foregoing condition, the evenness and smoothness of plating surface in each micro hole are ensured, also making all the surfaces of micro holes to have the same heights. Further, when the micro holes are made on a resist layer, the resist will not be peeled off.

Further, a micro-hole plating method according to the present invention is a method for carrying out gold plating within a micro hole, comprising the step of: depositing a gold layer within a micro hole by applying a plating current, which is a positive/negative current pulse wave, using a gold plating solution containing gold iodide complex ions and a non-aqueous solvent.

According to this method, gold plating is carried out within a micro hole by applying a plating current, which is a positive/negative current pulse wave, from a pulse source. Therefore, by using an appropriate pulse current waveform; that is, by making the positive current density, the negative current density, the positive pulse time, and the negative pulse time to appropriate values, the evenness and smoothness of plating surface in each micro hole are ensured, also making all the surfaces of micro holes to have the same heights. The effect is more significant in this case than the case above using a positive-only current pulse wave. Further, this case also prevents exfoliation of the resist even when the plating is carried out onto the micro holes formed on a resist layer.

The positive/negative current pulse wave is set such that a positive current density CDf (mA/cm²) satisfies 0<CDf<20, a negative current density CDr (mA/cm²) satisfies −20<CDr<0, a positive pulse time Tf [msec] satisfies 0<Tf<10000, and a negative pulse time Tr [msec] satisfies Tr>0.5. Therefore, by applying a plating current satisfying the foregoing condition, the evenness and smoothness of plating surface in each micro hole are ensured, also making all the surfaces of micro holes to have the same heights.

A gold bump forming method according to the present invention is a method for forming gold bumps on electrode pads formed on a substrate, comprising the step of: depositing a gold layer within a micro hole of a resist layer laminated on an electrode-pad-forming-surface of a substrate, by applying a plating current, which is a positive current pulse wave, using a gold plating solution containing gold iodide complex ions and a non-aqueous solvent.

According to this method, the gold bumps are formed by the foregoing micro-hole plating method of the present invention, which offers an effect of ensuring the evenness and smoothness of plating surface in each micro hole, making all the surfaces of micro holes to have the same heights, and preventing exfoliation of the resist even when the plating is carried out onto the micro holes formed on a resist layer.

Owning to this fact, this plating method is applicable for forming gold bumps, offering the effect of reducing unevenness of bump surface, bump height variation in the wafer, and the bump surface roughness. As a result, the reliability of conduction between the gold bumps are ensured, avoiding a short circuit between electrodes caused by a crack in the resist.

A method for fabricating a semiconductor device according to the present invention is arranged so that gold bumps are formed on electrode pads, the method comprising the step of: (i) forming the gold bumps on the electrode pads, the step (i) comprising the sub-steps of: (a) forming a resist layer on a substrate on which a semiconductor device is formed with electrode pads; (b) forming micro holes on the resist layer; and (c) depositing a gold layer within each of the micro holes by applying a plating current, which is a positive current pulse wave, using a gold plating solution containing gold iodide complex ions, and a non-aqueous solvent.

A semiconductor device according to the present invention is arranged so that gold bumps are formed on electrode pads, wherein: each of the gold bumps is formed by depositing a gold layer within a micro hole by applying a plating current, which is a positive current pulse wave, using a gold plating solution containing gold iodide complex ions, and a non-aqueous solvent.

With this arrangement, it is possible to manufacture a semiconductor device by forming gold bumps on the electrodes with the foregoing micro-hole plating method of the present invention, which offers an effect of ensuring the evenness and smoothness of plating surface in each micro hole, making all the surfaces of micro holes to have the same heights, and preventing exfoliation of the resist even when the plating is carried out onto the micro holes formed on a resist layer.

Owning to this fact, this plating method is applicable for forming gold bumps in fabrication of a semiconductor device, offering the effect of reducing unevenness of bump surface, bump height variation in the wafer, and the bump surface roughness. In the resulting semiconductor device, the reliability of conduction between the gold bumps are ensured, avoiding a decrease in yield due to short circuit between electrodes caused by a crack in the resist. On this account, it is possible to manufacture a semiconductor device with a high yield.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A micro-hole plating method for carrying out gold plating within a micro hole, comprising the step of:
depositing a gold layer within a micro hole by applying a plating current, which is a positive current pulse wave, using a gold plating solution containing gold iodide complex ions and a non-aqueous solvent.

2. The micro-hole plating method as set forth in claim 1, wherein:
the positive current pulse wave is set such that a current density CD (mA/cm²) satisfies 0<CD<20, a pulse-ON time Ton [msec] satisfies 0<Ton<10000, and a pulse-OFF time Toff [msec] satisfies Toff>0.5.

3. A micro-hole plating method for carrying out gold plating within a micro hole, comprising the step of:
depositing a gold layer within a micro hole by applying a plating current, which is a positive/negative current pulse wave, using a gold plating solution containing gold iodide complex ions and a non-aqueous solvent.

4. The micro-hole plating method as set forth in claim 3, wherein:
the positive/negative current pulse wave is set such that a positive current density CDf (mA/cm²) satisfies 0<CDf<20, a negative current density CDr (mA/cm²) satisfies −20<CDr<0, a positive pulse time Tf [msec] satisfies 0<Tf<10000, and a negative pulse time Tr [msec] satisfies Tr>0.5.

5. A gold bump forming method for forming gold bumps on electrode pads formed on a substrate, comprising the step of:
depositing a gold layer within a micro hole of a resist layer laminated on an electrode-pad-forming-surface of a substrate, by applying a plating current, which is a positive current pulse wave, using a gold plating solution containing gold iodide complex ions and a non-aqueous solvent.

6. A gold bump forming method for forming gold bumps on electrode pads formed on a substrate, comprising the step of:
depositing a gold layer within a micro hole of a resist layer laminated on an electrode-pad-forming-surface of a substrate, by applying a plating current, which is a positive/negative current pulse wave, using a gold plating solution containing gold iodide complex ions, and a non-aqueous solvent.

7. A method for fabricating a semiconductor device in which gold bumps are formed on electrode pads, comprising the step of:
(i) forming the gold bumps on the electrode pads,
the step (i) comprising the sub-steps of:
(a) forming a resist layer on a substrate on which a semiconductor device is formed with electrode pads;
(b) forming micro holes on the resist layer; and
(c) depositing a gold layer within each of the micro holes by applying a plating current, which is a positive current pulse wave, using a gold plating solution containing gold iodide complex ions, and a non-aqueous solvent.

8. A method for fabricating a semiconductor device in which gold bumps are formed on electrode pads, comprising the step of:
(i) forming the gold bumps on the electrode pads,
the step (i) comprising the sub-steps of:
(a) forming a resist layer on a substrate on which a semiconductor device is formed with electrode pads;
(b) forming micro holes on the resist layer; and
(c) depositing a gold layer within each of the micro holes by applying a plating current, which is a positive/negative current pulse wave, using a gold plating solution containing gold iodide complex ions, and a non-aqueous solvent.

9. A semiconductor device in which gold bumps are formed on electrode pads, wherein:
each of the gold bumps is formed by depositing a gold layer within a micro hole by applying a plating current, which is a positive current pulse wave, using a gold plating solution containing gold iodide complex ions, and a non-aqueous solvent.

10. A semiconductor device in which gold bumps are formed on electrode pads, wherein:
each of the gold bumps is formed by depositing a gold layer within a micro hole by applying a plating current, which is a positive/negative current pulse wave, using a gold plating solution containing gold iodide complex ions, and a non-aqueous solvent.
